(19) United States
(12) Patent Application Publication
(10) Pub. No.: US 2026/0155796 A1
(43) Pub. Date: Jun. 4, 2026

(54) DIFFERENTIAL AMPLIFICATION SYSTEM

(71) Applicant: Renesas Electronics America Inc., Milpitas, CA (US)

(72) Inventors: Philippe CONVERS, Zurich (CH); Bortecene TERLEMEZ, Zurich (CH)

(73) Assignee: Renesas Electronics America Inc., Milpitas, CA (US)

(21) Appl. No.: 18/965,338

(22) Filed: Dec. 2, 2024

(51) Int. Cl. H03F 3/45; H03F 1/32

(52) U.S. Cl. CPC H03F 3/4508; H03F 1/3211; H03F 2200/462; H03F 2203/45024

(57) ABSTRACT

A differential amplification system for receiving first and second input signals, and for generating first and second differential output signals, the differential amplification system comprising a differential amplifier configured to receive the first input signal and the second input signal, provide a first output current at a first current channel, and provide a second output current at a second current channel, a cascode stage configured to receive the first and second output currents, and generate the first and second differential output signals, a detector configured to detect when the first output current flowing through the first current channel meets a first condition, and/or detect when the second output current flowing through the second current channel meets a second condition, wherein a current sink stage configured to redirect at least a portion of the first output current and at least a portion of the second output current away from the cascode stage when the first condition is met by the first output current, and/or redirect at least a portion of the first output current and at least a portion of the second output current away from the cascode stage when the second condition is met by the second output current, wherein the first condition is met by the first output current when the first output current falls below a first threshold current value and/or the first output current rises above the first threshold current value, and the second condition is met by the second output current when the second output current falls below a second threshold current value and/or the second output current rises above the second threshold current value.

The present disclosure relates to a differential amplification system.

### BACKGROUND

FIG. 1A is a schematic of a known differential amplification system 100 (which may be referred to as a “differential stage”). During operation differential amplification system 100 receives input signals In_p and In_n and provides differential output signals Out_n and Out_p.

“Clipping” refers to a process of limiting the amplitude of the differential output signals Out_n, Out_p. The system of FIG. 1A demonstrates a known method of “clipping” the output of a differential stage.

The differential amplification system 100 comprises a variable gain amplifier 102 and a peak detector 104. During operation, the gain of the variable gain amplifier 102 is adjusted when the peak detector 104 detects an imminent overload. Specifically, when the output amplitude of the differential output signals Out_n, Out_p exceeds a desired maximum limit, the peak detector 104 reduces the variable gain amplifier's 102 gain, thereby reducing the output amplitude.

This technique can be very accurate and sensitive but is typically slow. As it is slow, the output will go beyond the specified clipping voltage until the loop settles.

FIG. 1B is a schematic of a further known differential amplification system 106 comprising diodes 108, 110 that are used to limit the amplitude of the output signals Out_n, Out_p, thereby providing “clipping” using diodes.

If the diodes were ideal they would have both a fast and a sharp behaviour. However, real diodes have an exponential response, so the limiting is fast but not very sharp, and will distort the signal when it gets close to the limit, which may be undesirable.

### SUMMARY

It is desirable to provide an improved differential amplification system for clipping output signals. It is desirable to provide an improved differential amplification system that is sharp and/or fast when clipping.

According to a first aspect of the disclosure there is provided a differential amplification system for receiving first and second input signals, and for generating first and second differential output signals, the differential amplification system comprising a differential amplifier configured to receive the first input signal and the second input signal, provide a first output current at a first current channel, and provide a second output current at a second current channel, a cascode stage configured to receive the first and second output currents, and generate the first and second differential output signals, a detector configured to detect when the first output current flowing through the first current channel meets a first condition, and/or detect when the second output current flowing through the second current channel meets a second condition, and a current sink stage configured to redirect at least a portion of the first output current and at least a portion of the second output current away from the cascode stage when the first condition is met by the first output current, and/or redirect at least a portion of the first output current and at least a portion of the second output current away from the cascode stage when the second condition is met by the second output current, wherein the first condition is met by the first output current when the first output current falls below a first threshold current value and/or the first output current rises above the first threshold current value, and the second condition is met by the second output current when the second output current falls below a second threshold current value and/or the second output current rises above the second threshold current value.

Optionally, the differential amplifier comprises a first current source coupled to a first node, a first transistor comprising a first transistor first terminal configured to receive the first input signal, a first transistor second terminal coupled to the first current channel, a first transistor third terminal coupled to the first node, and a second transistor comprising a second transistor first terminal configured to receive the second input signal, a second transistor second terminal coupled to the second current channel, a second transistor third terminal coupled to the first node.

Optionally, the differential amplifier comprises a first resistor, the first transistor third terminal being coupled to the first node via the first resistor, and a second resistor, the second transistor third terminal being coupled to the first node via the second resistor.

Optionally, the first transistor is a first bipolar transistor, the first transistor first terminal is a first transistor base terminal, the first transistor second terminal is a first transistor collector terminal, the first transistor third terminal is a first transistor emitter terminal, the second transistor is a second bipolar transistor, the second transistor first terminal is a first transistor base terminal, the second transistor second terminal is a second transistor collector terminal, and the second transistor third terminal is a second transistor emitter terminal.

Optionally, the cascode stage comprises a third bipolar transistor comprising a third transistor first terminal, a third transistor second terminal configured to provide the first differential output signal, a third transistor third terminal coupled to the first current channel, a fourth bipolar transistor comprising a fourth transistor first terminal coupled to the third transistor first terminal, a fourth transistor second terminal configured to provide the second differential output signal, and a fourth transistor third terminal coupled to the second current channel.

Optionally, the third transistor first terminal is a third transistor base terminal, the third transistor second terminal is a third transistor collector terminal, the third transistor third terminal is a third transistor emitter terminal, the fourth transistor first terminal is a fourth transistor base terminal, the fourth transistor second terminal is a fourth transistor collector terminal, and the fourth transistor third terminal is a fourth transistor emitter terminal.

Optionally, the detector comprises a first detector input coupled to the first current channel to detect the first output current, and a second detector input coupled to the second current channel to detect the second output current.

Optionally, the detector is configured to activate the current sink stage to redirect the at least at a portion of the first output current and the at least a portion of the second output current when the detector detects that the first condition has been met, and/or activate the current sink stage to redirect the at least a portion of the first output current and the at least a portion of the second output current when the detector detects that the second condition has been met.

Optionally, the current sink stage comprises a first sink switch, a second sink switch, and a current sink coupled to the first current channel via the first sink switch and coupled to the second current channel via the second sink switch, wherein the detector is configured to activate the first sink switch and the second sink switch to redirect the at least at a portion of the first output current and the at least a portion of the second output current when the detector detects that the first condition has been met, and/or activate the first sink switch and the second sink switch to redirect the at least a portion of the first output current and the at least a portion of the second output current when the detector detects that the second condition has been met.

Optionally, the first sink switch is a first sink bipolar transistor, the second sink switch is a second bipolar transistor, wherein the detector is configured to activate the first sink bipolar transistor by providing a first activation signal to a first sink bipolar transistor base terminal, and/or the detector is configured to activate the second sink bipolar transistor by providing a second activation signal to a second sink bipolar transistor base terminal.

Optionally, the current sink comprises a voltage source.

Optionally, the detector is configured to receive a reference voltage, the first threshold current value is dependent on the reference voltage and/or the second threshold current value is dependent on the reference voltage.

Optionally, the differential amplification system comprises a reference voltage generator configured to generate the reference voltage.

Optionally, the reference voltage generator comprises a second current source coupled to a second node, a first reference generator bipolar transistor comprising a base terminal coupled to the cascode stage and an emitter terminal coupled to the second node, a second reference generator bipolar transistor comprising a base terminal coupled to the current sink stage and an emitter terminal coupled to the second node, wherein the reference voltage is provided at the second node.

Optionally, the detector comprises a rectifier circuit comprising a first rectifier input coupled to the first current channel, a second rectifier input coupled to the second current channel, a third rectifier input for receiving the reference voltage, a first rectifier output for providing a first activation signal to the current sink stage to activate the current sink stage to redirect the at least at a portion of the first output current and the at least a portion of the second output current when the detector detects that the first condition has been met, and/or a second rectifier output for providing a second activation signal to the current sink stage to activate the current sink stage to redirect the at least a portion of the first output current and the at least a portion of the second output current when the detector detects that the second condition has been met.

Optionally, the rectifier circuit comprises a first rectifier bipolar transistor comprising the first rectifier input, a second rectifier bipolar transistor comprising the second rectifier input, and a third rectifier bipolar transistor comprising the third rectifier input.

Optionally, the detector comprises a comparator.

Optionally, the cascode stage comprises a third bipolar transistor comprising a third transistor base terminal, a third transistor collector terminal configured to provide the first differential output signal, a third transistor emitter terminal coupled to the first current channel, a fourth bipolar transistor comprising a fourth transistor base terminal coupled to the third transistor first terminal, a fourth transistor collector terminal configured to provide the second differential output signal, and a fourth transistor emitter terminal coupled to the second current channel, the current sink stage comprises a first sink bipolar transistor, a second sink bipolar transistor, and a current sink coupled to the first current channel via the first sink switch and coupled to the second current channel via the second sink switch, wherein the detector is configured to activate the current sink stage by activating the first sink bipolar transistor by providing a first activation signal to a first sink bipolar transistor base terminal and by activating the second sink bipolar transistor by providing the first activation signal to a second sink bipolar transistor base terminal, thereby redirecting the at least at a portion of the first output current and the at least a portion of the second output current when the detector detects that the first condition has been met, and/or activate the current sink stage by activating the first sink bipolar transistor by providing a second activation signal to the first sink bipolar transistor base terminal and by activating the second sink bipolar transistor by providing the second activation signal to a second sink bipolar transistor base terminal, thereby redirecting the at least a portion of the first output current and the at least a portion of the second output current when the detector detects that the second condition has been met;

Optionally, the differential amplification system comprises an output terminal coupled to the third transistor collector terminal, the fourth transistor collector terminal, a first sink bipolar transistor collector terminal and a second sink bipolar transistor collector terminal.

According to a second aspect of the disclosure there is provided a method of providing a differential amplification system for receiving first and second input signals, and for generating first and second differential output signals, the method comprising providing a differential amplifier configured to receive the first input signal and the second input signal, provide a first output current at a first current channel, and provide a second output current at a second current channel, providing a cascode stage configured to receive the first and second output currents, and generate the first and second differential output signals, providing a detector configured to detect when the first output current flowing through the first current channel meets a first condition, and/or detect when the second output current flowing through the second current channel meets a second condition, and providing a current sink stage configured to redirect at least a portion of the first output current and at least a portion of the second output current away from the cascode stage when the first condition is met by the first output current, and/or redirect at least a portion of the first output current and at least a portion of the second output current away from the cascode stage when the second condition is met by the second output current, wherein the first condition is met by the first output current when the first output current falls below a first threshold current value and/or the first output current rises above the first threshold current value, and the second condition is met by the second output current when the second output current falls below a second threshold current value and/or the second output current rises above the second threshold current value.

It will be appreciated that the method of the second aspect may include providing and/or using features set out in the first aspect and can incorporate other features as described herein.

### BRIEF DESCRIPTION OF THE DRAWINGS

The disclosure is described in further detail below by way of example and with reference to the accompanying drawings in which:

FIG. 1A is a schematic of a known differential amplification system, FIG. 1B is a schematic of a further known differential amplification system;

FIG. 2A is a schematic of a differential amplification system in accordance with a first embodiment of the present disclosure, FIG. 2B is a schematic of a specific embodiment of the differential amplification system in accordance with a second embodiment of the present disclosure;

FIG. 3A is a schematic of a further specific embodiment of the differential amplification system in accordance with a third embodiment of the present disclosure, FIG. 3B is a further schematic of the differential amplification system as shown in FIG. 3A; and

FIG. 4A is a schematic of a further specific embodiment of the differential amplification system in accordance with a fourth embodiment of the present disclosure, FIG. 4B is a schematic of a specific embodiment of the detector.

### DETAILED DESCRIPTION

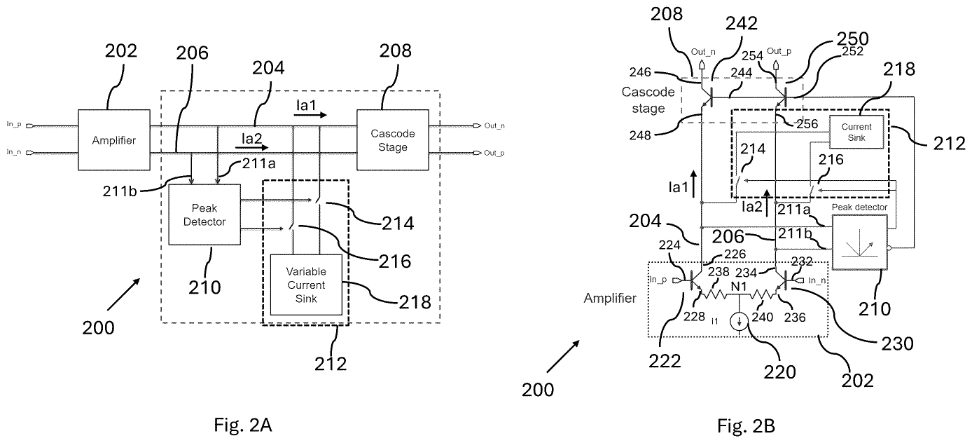

FIG. 2A is a schematic of a differential amplification system 200 in accordance with a first embodiment of the present disclosure. During operation, the differential amplification system 200 receives input signals In_p and In_n, and generates differential output signals Out_n and Out_p.

The differential amplification system 200 comprises a differential amplifier 202 that is configured to receive the input signals In_p, In_n. The differential amplifier 202 is further configured to provide an output current Ia1 at a current channel 204 and an output current Ia2 at a current channel 206.

The differential amplification system 200 further comprises a cascode stage 208 that is configured to receive the output currents Ia1, Ia2, and to generate the differential output signals Out_n, Out_p.

The differential amplification system 200 further comprises a detector 210 and a current sink stage 212. The detector 210 is configured to detect when the output current Ia1 flowing through the current channel 204 meets a first condition. The detector 210 may be referred to as a “peak detector”. The current sink stage 212 may comprise switches 214, 216 and a current sink 218.

The current sink stage 212 is configured to redirect at least a portion of the output current Ia1 and at least a portion of the output current Ia2 away from the cascode stage 208 when the first condition is met.

The first condition may be met by the output current Ia1 when the output current Ia1 falls below a first threshold current value. Alternatively, or additionally, the first condition may be met when the output current Ia1 rises above the first threshold current value.

The detector 210 may be further configured to detect when the output current Ia2 flowing through the current channel 206 meets a second condition. The current sink stage may be configured to redirect at least a portion of the output current Ia1 and at least a portion of the output current Ia2 away from the cascode stage 208 when the second condition is met.

The second condition may be met by the output current Ia2 when the output current Ia2 falls below a second threshold current value. Alternatively, or additionally, the second condition may be met when the output current Ia2 rises above the second threshold current value.

The detector 210 may comprise an input 211a coupled to the channel 204 to detect the output current Ia1 and may comprise an input 211b coupled to the channel 206 to detect the output current Ia2. The detector 210 may be configured to activate the current sink stage 212 to redirect the at least a portion of the output current Ia1 and the at least a portion of the second output current Ia2 when the first condition is met and/or may be configured to activate the current sink stage 212 to redirect the at least a portion of the first output current Ia1 and the at least a portion of the output current Ia2 when the second condition is met. The detector 210 may activate the current sink stage 212 by controlling the switch 214 and/or the switch 216.

In summary, during operation the input of the cascode stage 208 is sensed by the detector 210. The detector 210 is coupled to the inputs of the cascode stage 208 to measure the current flowing towards each input of the cascode stage 208. If the detector 210 detects that a current in one of the channels of the input stage falls below a certain threshold, then a current sink path is activated. Thus, current that would otherwise be directed to the output of the cascode stage 208 is directed to the current sink 218, preventing overloading. Therefore, embodiments of the differential amplification system 200 provide a sharp and a quick way to clip a differential signal.

FIG. 2B is a schematic of a specific embodiment of the differential amplification system 200 in accordance with a second embodiment of the present disclosure.

In the present embodiment, the differential amplifier 202 comprises a current source 220 for providing a current I1 and coupled to a node N1.

The differential amplifier 202 further comprises a transistor 222 which receives the input voltage In_p at a terminal 224. The transistor 222 further comprises a terminal 226 coupled to the current channel 204 and a terminal 228 coupled to the node N1.

The differential amplifier 202 further comprises a transistor 230 which receives the input voltage In_n at a terminal 232. The transistor 230 further comprises a terminal 234 coupled to the current channel 206 and a terminal 236 coupled to the node N1.

In the present embodiment, the differential amplifier 202 further comprises a resistor 238 with the transistor 222 being coupled to the node N1 via the resistor 238, and a resistor 240 with the transistor 230 coupled to the node N1 via the resistor 240.

In the present embodiment the transistors 222, 230 are bipolar transistors. In the present embodiment, the transistor 222 receives the input voltage In_P at its base terminal and the transistor 230 receives the input voltage In_n at its base terminal. In the present embodiment, the terminals 226, 234 are collector terminals, and the terminals 228, 236 are emitter terminals.

In the present embodiment, the cascode stage 208 comprises a bipolar transistor 242 having a terminal 244, a terminal 246 for providing the differential output signal Out_n, and a terminal 248 coupled to the current channel 204. In the present embodiment, the terminal 244 is a base terminal, the terminal 246 is a collector terminal and the terminal 248 is an emitter terminal.

In the present embodiment, the cascode stage 208 further comprises a bipolar transistor 250 having a terminal 252, a terminal 254 for providing the differential output signal Out_p, and a terminal 256 coupled to the current channel 206. In the present embodiment, the terminal 252 is a base terminal, the terminal 254 is a collector terminal and the terminal 256 is an emitter terminal. The base terminals of the transistors 242, 250 may be coupled together.

The bipolar transistors 242, 250 be referred to as bipolar junction transistors (BJT). In the present embodiment, the use of BJT transistors in the cascode stage 208 improves the speed of the cascode stage 208 as the transistors 208 are coupled in a common base topology. In further embodiments, the cascode stage 208 may be implemented using metal oxide field effect transistors (MOSFET), in accordance with the understanding of the skilled person.

The voltage swing at the emitter of a common base transistor is typically low, however it increases exponentially when the emitter current gets small. Thus, by detecting a low current on the emitter of one of the transistors 242, 250 of the cascode stage 208, it can be determined that the signal swing on the output of the cascode stage 208 will be too high, thereby leading to overload.

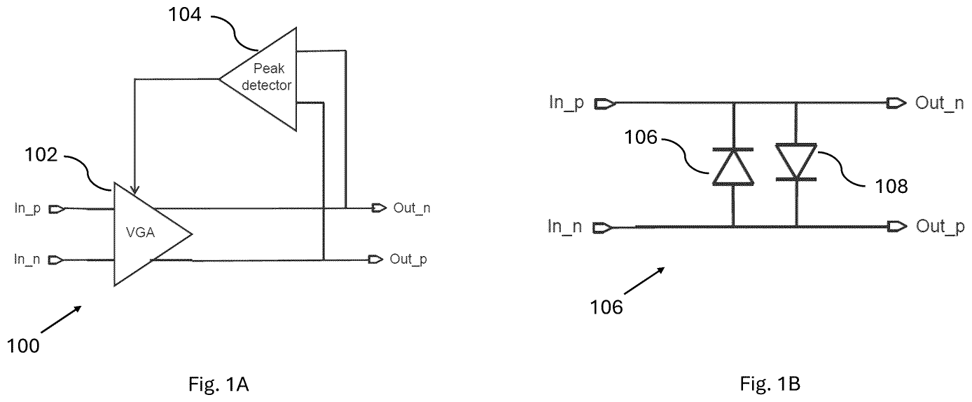

In contrast to known systems such as the system presented in FIG. 1A, the detector 210 of embodiments of the present disclosure does not change the gain of an amplifier to reduce the likelihood of clipping. Instead, the detector 210 subtracts current from its output, and uses the input of the cascode stage 208 as a trigger for this subtraction.

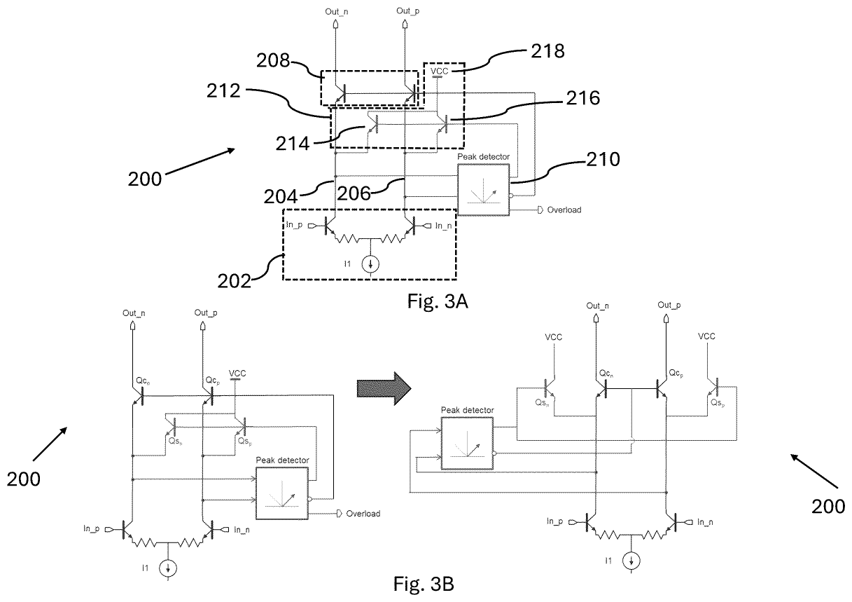

FIG. 3A is a schematic of a further specific embodiment of the differential amplification system 200 in accordance with a third embodiment of the present disclosure.

In the present embodiment, there is shown a specific embodiment of the current sink stage 212. Specifically, the switches 214, 216 are each bipolar transistors, which may be in a common base arrangement, where their bases are coupled together. In a further embodiment, each of the switches 214, 216 may be a MOSFET, in accordance with the understanding of the skilled person.

During operation, the detector 210 may provide activation signals to the base terminals of the switches 214, 216 in response to the necessary output current Ia1, Ia2 conditions being met as described previously. In the present embodiment the current sink 218 comprises a voltage source Vcc.

The switches 214, 216 implemented by bipolar transistors may be referred to as bipolar junction transistors (BJT).

In summary, during operation, when the detector 210 detects current on either of the two channels 204, 206 falling below a certain threshold it turns on the BJT transistors (the switches 214, 216) of the current sink stage 212. This in turn directs part of the signal to the voltage source Vcc, thereby reducing the output amplitude of the differential output signals Out_n, Out_p. Thus, a fraction of the current (both DC and RF) gets diverted through the current sink 218.

FIG. 3B is a further schematic of the differential amplification system 200 as shown in FIG. 3A. The leftmost schematic shows the differential amplification stage 200 arranged as illustrated in FIG. 3A and the rightmost schematic shows the same differential amplification stage 200 with an alternative schematic layout. The rightmost image is used to demonstrate similarities in structure to a Gilbert Cell. Structurally there are similarities between embodiments of the present disclosure and Gilbert Cells. However, Gilbert Cells are used as frequency mixers and therefore function differently from the embodiments of the present disclosure. Furthermore, Gilbert Cells do not include peak detectors such as the detector 210.

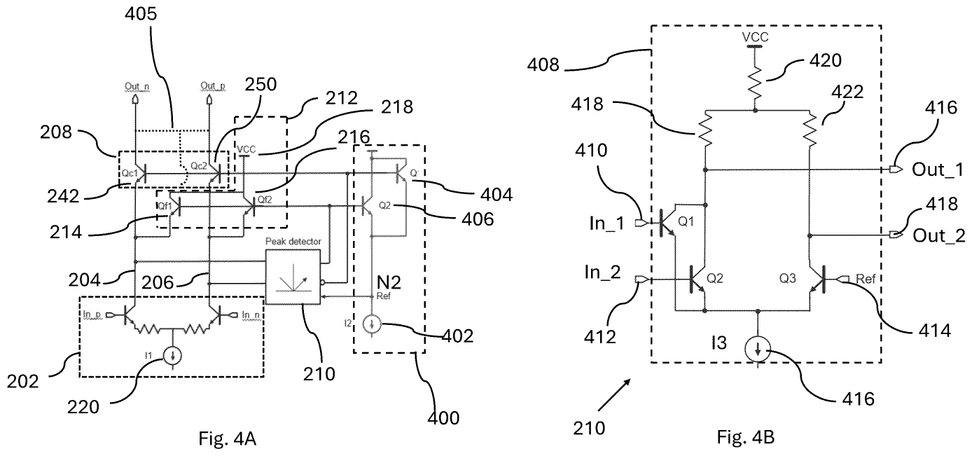

FIG. 4A is a schematic of a further specific embodiment of the differential amplification system 200 in accordance with a fourth embodiment of the present disclosure.

In the present embodiment, the detector 210 is configured to receive a reference voltage Ref. The first threshold current value used for the evaluation of the first condition may be dependent on the reference voltage Ref. The second threshold current value used for the evaluation of the second condition may be dependent on the reference voltage Ref.

The differential amplification system 200 may comprise a reference voltage generator 400 for generating the reference voltage Ref.

The reference voltage generator 400 may comprise a current source 402 coupled to a node N2 and bipolar transistors 404, 406. In the present embodiment, the bipolar transistor 404 has its base terminal coupled to the cascode stage 208 and its emitter terminal coupled to the node N2. In the present embodiment, the bipolar transistor 406 has its base terminal coupled to the current sink stage 212 and has its emitter terminal coupled to the node N2. During operating, the reference voltage Ref may be provided at the node N2.

In a further embodiment, the collector terminals of the cascode stage 208 bipolar transistors 242, 250 may be coupled together and coupled to the collector terminals of the bipolar transistors 214, 216 of the current sink stage 212 to provide a single output terminal 405 for providing a single differential output signal.

FIG. 4B is a schematic of a specific embodiment of the detector 210 as may be used in any of the embodiments described herein, in accordance with the understanding of the skilled person. In the present embodiment, the detector 210 comprises a rectifier circuit 408.

The rectifier circuit 408 comprises an input 410 for coupling to the current channel 204, and for receiving an input signal In_1 from the current channel 204, the input signal In_1 being dependent on the current Ia1. The rectifier circuit 408 further comprises an input 412 for coupling to the current channel 206, and for receiving an input signal In_2 from the current channel 206, the input signal In_2 being dependent on the current Ia2. The rectifier circuit 408 further comprises an input 414 for receiving the reference voltage Ref. The rectifier circuit 408 further comprises an output 416 for providing an activation signal Out_1 to the current sink stage 212 to activate the current sink stage 212, for example, in response to the output current Ia1 meeting the first condition to redirect both output currents Ia1, Ia2 to the current sink 218. The rectifier circuit 408 further comprises an output 418 for providing an activation signal Out_2 to the current sink stage 212 to activate the current sink stage 212, for example, in response to the output current Ia2 meeting the second condition to redirect both output currents, Ia1 Ia2 to the current sink 218.

The rectifier circuit 408 may comprise a transistor Q1 comprising the input 410, a transistor Q2 comprising the input 412 a transistor Q3 comprising the input 414.

The rectifier circuit 408 may further comprise a current source 416 and resistors 418, 420, 422.

In a further embodiment, the detector 210 may comprise a comparator instead of the rectifier circuit 408. However, there rectifier circuit 408 offers the following benefits over a comparator:
a) It enables adjusting the voltage at the base of the transistor of the cascode stage 208 inversely to the adjustment on the base of the transistor of the current sink stage 218.
b) It is smaller in area, faster and of reduced complexity than using a conventional comparator.

Preferably, the voltage reference Ref for the detector 210 is very accurate to set the proper clipping level and to tolerate changes in temperature and/or process. To achieve this, the reference voltage generator 400 is coupled to the cascode stage 208, the current sink stage 212 and the detector 210.

During operation, the transistor 404 creates a diode drop from the cascode base voltage. The reference voltage Ref then depends on the ratio between the transistors 242, 250, 404 and the ratio between the current I1 of the current source 220 and the current I2 of the current source 402. The reference voltage Ref is stable with temperature and process, because the transistor 404 mirrors the transistors 242, 250.

The transistor 406 takes over setting the reference Ref during the clipping operation. Without the transistor 406 coupled as seen in FIG. 4A, when the detector 210 activates the transistors 214, 216, a positive feedback would occur which would eventually result in all of the current being directed to the current sink 218 instead of the cascode stage 208.

More specifically, as current is directed to the current sink Vcc, the voltage on the emitters of the transistors 214, 216, 242, 250 increases, which is equivalent to the detector 210 detecting an even lower current. Thus when clipping happens, transistors 214, 216 result in the detector 210 sensing an even greater amount of overload, thus adjusting the voltage at the bases of the transistors 214, 216 in a manner that would direct even more current towards Vcc.

By coupling the transistor 406 as shown in FIG. 4A, the transistor 406 raises the reference voltage Ref in an overload situation to compensate for the positive feedback described above, thus avoiding latching.

In summary, in embodiments of the present disclosure, if an emitter current is less than a reference value, the detector 210 activates a path which allows some of the current that would normally be directed to the cascode stage 208 to be redirected away from the output (by leading it to the variable current sink 218). This in turn reduces the amplitude of the output, preventing overloading.

In specific embodiments, it will be appreciated that due to the characteristics of the differential amplifier 202, a low current on the emitter of one of the common base transistors may result in a high current on the other common base transistor. Therefore, in further embodiments the detector 210 may be configured to detect current on one of the channels exceeding a threshold, and activating the current sink operation in relation to the current exceeding the threshold value.

It will be appreciated that in further embodiments, the bipolar junction transistors of embodiments of the present disclosure may alternatively be implemented using other transistor types, such as metal oxide semiconductor field effect transistors (MOSFETs), in accordance with the understanding of the skilled person.

In summary, embodiments of the present disclosure provide a sharper and faster way of clipping a differential signal when compared with known systems.

Common reference numerals and variables between figures represent common features.

Various improvements and modifications may be made to the above without departing from the scope of the disclosure.

1. A differential amplification system for receiving first and second input signals, and for generating first and second differential output signals, the differential amplification system comprising:
a differential amplifier configured to:
receive the first input signal and the second input signal;
provide a first output current at a first current channel; and
provide a second output current at a second current channel;
a cascode stage configured to:
receive the first and second output currents; and
generate the first and second differential output signals;
a detector configured to:
detect when the first output current flowing through the first current channel meets a first condition; and/or
detect when the second output current flowing through the second current channel meets a second condition; and
a current sink stage configured to:
redirect at least a portion of the first output current and at least a portion of the second output current away from the cascode stage when the first condition is met by the first output current; and/or
redirect at least a portion of the first output current and at least a portion of the second output current away from the cascode stage when the second condition is met by the second output current; wherein:
the first condition is met by the first output current when the first output current falls below a first threshold current value and/or the first output current rises above the first threshold current value; and
the second condition is met by the second output current when the second output current falls below a second threshold current value and/or the second output current rises above the second threshold current value.

2. The differential amplification system of claim 1 wherein:
the differential amplifier comprises:
a first current source coupled to a first node;
a first transistor comprising:
a first transistor first terminal configured to receive the first input signal;
a first transistor second terminal coupled to the first current channel;
a first transistor third terminal coupled to the first node; and
a second transistor comprising:
a second transistor first terminal configured to receive the second input signal;
a second transistor second terminal coupled to the second current channel;
a second transistor third terminal coupled to the first node.

3. The differential amplification system of claim 2, wherein:
the differential amplifier comprises:
a first resistor, the first transistor third terminal being coupled to the first node via the first resistor; and
a second resistor, the second transistor third terminal being coupled to the first node via the second resistor.

4. The differential amplification system of claim 2, wherein:
the first transistor is a first bipolar transistor;
the first transistor first terminal is a first transistor base terminal;
the first transistor second terminal is a first transistor collector terminal;
the first transistor third terminal is a first transistor emitter terminal;
the second transistor is a second bipolar transistor;
the second transistor first terminal is a first transistor base terminal;
the second transistor second terminal is a second transistor collector terminal; and
the second transistor third terminal is a second transistor emitter terminal.

5. The differential amplification system of claim 1, wherein:
the cascode stage comprises:
a third bipolar transistor comprising:
a third transistor first terminal;
a third transistor second terminal configured to provide the first differential output signal;
a third transistor third terminal coupled to the first current channel;
a fourth bipolar transistor comprising:
a fourth transistor first terminal coupled to the third transistor first terminal;
a fourth transistor second terminal configured to provide the second differential output signal; and
a fourth transistor third terminal coupled to the second current channel.

6. The differential amplification system of claim 5, wherein the:
the third transistor first terminal is a third transistor base terminal;
the third transistor second terminal is a third transistor collector terminal;
the third transistor third terminal is a third transistor emitter terminal;
the fourth transistor first terminal is a fourth transistor base terminal;
the fourth transistor second terminal is a fourth transistor collector terminal; and
the fourth transistor third terminal is a fourth transistor emitter terminal.

7. The differential amplification system of claim 1 wherein:
the detector comprises:
a first detector input coupled to the first current channel to detect the first output current; and
a second detector input coupled to the second current channel to detect the second output current.

8. The differential amplification system of claim 1, wherein:
the detector is configured to:
activate the current sink stage to redirect the at least at a portion of the first output current and the at least a portion of the second output current when the detector detects that the first condition has been met; and/or
activate the current sink stage to redirect the at least a portion of the first output current and the at least a portion of the second output current when the detector detects that the second condition has been met.

9. The differential amplification system of claim 8, wherein the current sink stage comprises:
a first sink switch;
a second sink switch; and
a current sink coupled to the first current channel via the first sink switch and coupled to the second current channel via the second sink switch; wherein:
the detector is configured to:
activate the first sink switch and the second sink switch to redirect the at least at a portion of the first output current and the at least a portion of the second output current when the detector detects that the first condition has been met; and/or
activate the first sink switch and the second sink switch to redirect the at least a portion of the first output current and the at least a portion of the second output current when the detector detects that the second condition has been met.

10. The differential amplification system of claim 9, wherein the:
the first sink switch is a first sink bipolar transistor;
the second sink switch is a second bipolar transistor; wherein:
the detector is configured to activate the first sink bipolar transistor by providing a first activation signal to a first sink bipolar transistor base terminal; and/or
the detector is configured to activate the second sink bipolar transistor by providing a second activation signal to a second sink bipolar transistor base terminal.

11. The differential amplification system of claim 10, wherein the current sink comprises a voltage source.

12. The differential amplification system of claim 1, wherein:
the detector is configured to receive a reference voltage;
the first threshold current value is dependent on the reference voltage and/or the second threshold current value is dependent on the reference voltage.

13. The differential amplification system of claim 12 comprising a reference voltage generator configured to generate the reference voltage.

14. The differential amplification system of claim 13, wherein the reference voltage generator comprises:
a second current source coupled to a second node;
a first reference generator bipolar transistor comprising a base terminal coupled to the cascode stage and an emitter terminal coupled to the second node;
a second reference generator bipolar transistor comprising a base terminal coupled to the current sink stage and an emitter terminal coupled to the second node; wherein:
the reference voltage is provided at the second node.

15. The differential amplification system of claim 12 wherein the detector comprises:
a rectifier circuit comprising:
a first rectifier input coupled to the first current channel;
a second rectifier input coupled to the second current channel;
a third rectifier input for receiving the reference voltage;
a first rectifier output for providing a first activation signal to the current sink stage to activate the current sink stage to redirect the at least at a portion of the first output current and the at least a portion of the second output current when the detector detects that the first condition has been met; and/or
a second rectifier output for providing a second activation signal to the current sink stage to activate the current sink stage to redirect the at least a portion of the first output current and the at least a portion of the second output current when the detector detects that the second condition has been met.

16. The differential amplification system of claim 15, wherein the rectifier circuit comprises a first rectifier bipolar transistor comprising the first rectifier input, a second rectifier bipolar transistor comprising the second rectifier input, and a third rectifier bipolar transistor comprising the third rectifier input.

17. The differential amplification system of claim 12, wherein the detector comprises a comparator.

18. The differential amplification system of claim 1, wherein:
the cascode stage comprises:
a third bipolar transistor comprising:
a third transistor base terminal;
a third transistor collector terminal configured to provide the first differential output signal;
a third transistor emitter terminal coupled to the first current channel;
a fourth bipolar transistor comprising:
a fourth transistor base terminal coupled to the third transistor first terminal;
a fourth transistor collector terminal configured to provide the second differential output signal; and
a fourth transistor emitter terminal coupled to the second current channel;
the current sink stage comprises:
a first sink bipolar transistor;
a second sink bipolar transistor; and
a current sink coupled to the first current channel via the first sink switch and coupled to the second current channel via the second sink switch; wherein:
the detector is configured to:
activate the current sink stage by activating the first sink bipolar transistor by providing a first activation signal to a first sink bipolar transistor base terminal and by activating the second sink bipolar transistor by providing the first activation signal to a second sink bipolar transistor base terminal, thereby redirecting the at least at a portion of the first output current and the at least a portion of the second output current when the detector detects that the first condition has been met; and/or
activate the current sink stage by activating the first sink bipolar transistor by providing a second activation signal to the first sink bipolar transistor base terminal and by activating the second sink bipolar transistor by providing the second activation signal to a second sink bipolar transistor base terminal, thereby redirecting the at least a portion of the first output current and the at least a portion of the second output current when the detector detects that the second condition has been met;

19. A method of providing a differential amplification system for receiving first and second input signals, and for generating first and second differential output signals, the method comprising:
providing a differential amplifier configured to:
receive the first input signal and the second input signal;
provide a first output current at a first current channel; and
provide a second output current at a second current channel;
providing a cascode stage configured to:
receive the first and second output currents; and
generate the first and second differential output signals;
providing a detector configured to:
detect when the first output current flowing through the first current channel meets a first condition; and/or
detect when the second output current flowing through the second current channel meets a second condition; and
providing a current sink stage configured to:
redirect at least a portion of the first output current and at least a portion of the second output current away from the cascode stage when the first condition is met by the first output current; and/or
redirect at least a portion of the first output current and at least a portion of the second output current away from the cascode stage when the second condition is met by the second output current; wherein:
the first condition is met by the first output current when the first output current falls below a first threshold current value and/or the first output current rises above the first threshold current value; and
the second condition is met by the second output current when the second output current falls below a second threshold current value and/or the second output current rises above the second threshold current value.
